(19) United States
(12) Patent Application Publication
(10) Pub. No.: US 2001/0033175 A1
(43) Pub. Date: Oct. 25, 2001

(54) Coil for automated mounting

(76) Inventors: Detlef Horst Marbach, Stassfurt (DE); Guenther Spee, Nettetal (DE); Hendricus Martinus Van Der Wijst, Veldhoven (NL)

Correspondence Address: Corporate Patent Counsel, U.S. Philips Corporation, 580 White Plains Road, Tarrytown, NY, 10591, US

(21) Appl. No.: 09/825,278

(22) Filed: Apr. 3, 2001

(30) Foreign Application Priority Data
Apr. 6, 2000 (DE) 10016974.0

(51) Int. Cl. G01R 31/06

(52) U.S. Cl. 324/546

(57) ABSTRACT

The present invention relaters to a coil (1) having a plurality of turns (2). The characteristic feature of the invention is that the turns (2) include a magnetic material or the turns (2) have an outer layer for carrying an electric current and have a magnetic material in their interior.

The present invention relates to a coil having a plurality of turns.

Modern electrical apparatuses often require many coils, which are mounted on the printed circuit boards of the relevant electrical apparatus. The coils should combine very good electrical properties with a compact construction and a great ease of mounting. From JP-A 06 036937 a coil having a magnetic core is known, in which the magnetic stray flux is minimized in that the turns of the coil and the core form a single part.

It is an object of the present invention to provide a coil having minimal stray losses through the air gap between the turns of the coil and which enables a simple and fully automatic mounting on a printed circuit board to be achieved.

With an air coil in accordance with the invention this object is achieved in that the turns include a magnetic material. According to the invention said object is achieved in that the turns include an outer layer for carrying an electric current and a magnetic material in their interior. Air gaps between individual turns of the coil produce a stray flux and adversely affect the electrical properties of such a coil. In order to avoid these air gaps the turns of a coil in accordance with the invention consist of magnetic wire. The individual turns of the coil are firmly held together by the magnetic forces between these turns, as a result of which air gaps between the turns are avoided. For this purpose, the turns of the coils need neither be glued together nor need they be wound onto a core or held together by other additional means. The coil is wound to the desired shape and retains its shape as a result of the magnetic forces between the turns. This allows a simple manufacture, particularly in the case of production in large quantities.

The embodiment defined in claim 3 is particularly suitable for uses in high frequency technology, which usually employs air coils without cores. In order to improve the conductivity for high frequency currents the magnetic wire from which the air coil is wound is clad with a material which is particularly suitable for high frequency uses. For this purpose, the magnetic wire is clad with a layer of cold, silver or copper.

The embodiment defined in claim 4 substantially facilitates the mounting of the coil. To enable the automatic mounting machine to detect the shape of the coil and its correct mounting direction the coil should provide the appropriate information to the automatic mounting machine. A simple possibility of providing this information is that the automatic mounting machine has a magnetic sensor which detects the degree and the type of magnetization of the coil to be mounted. Since the magnetization differs in dependence on the length of the coil and differently magnetized wires can be used different coils can be detected with the aid of their magnetic properties.

The embodiment defined in claim 5 enables the coil to be mounted fully automatically on printed circuit boards. Particularly in the case of SMD mounting (Surface Mounted Device) this enables a high production rate to be obtained. During SMD mounting the parts are secured to that side of the printed circuit board, on which they are mounted.

An embodiment of the present invention will now be described in more detail by way of example with reference to several Figures. In the drawings:

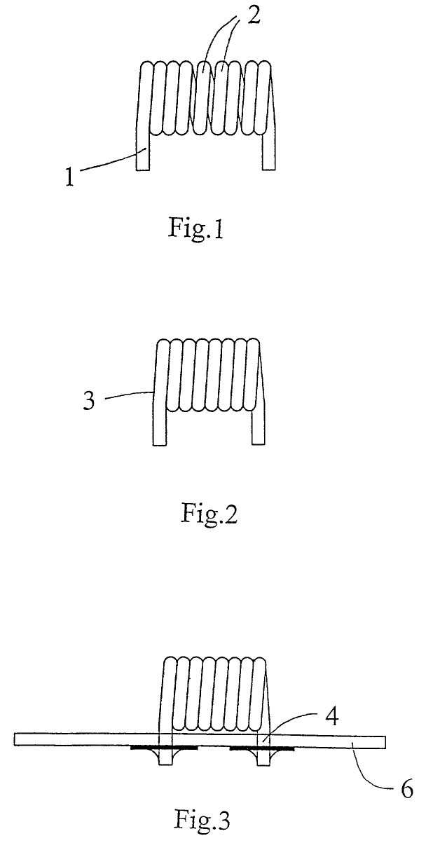

FIG. 1 shows a conventional air coil,

FIG. 2 shows an air coil of magnetic wire in accordance with the invention.

FIG. 3 shows the air coil in accordance with the invention mounted on a printed circuit board,

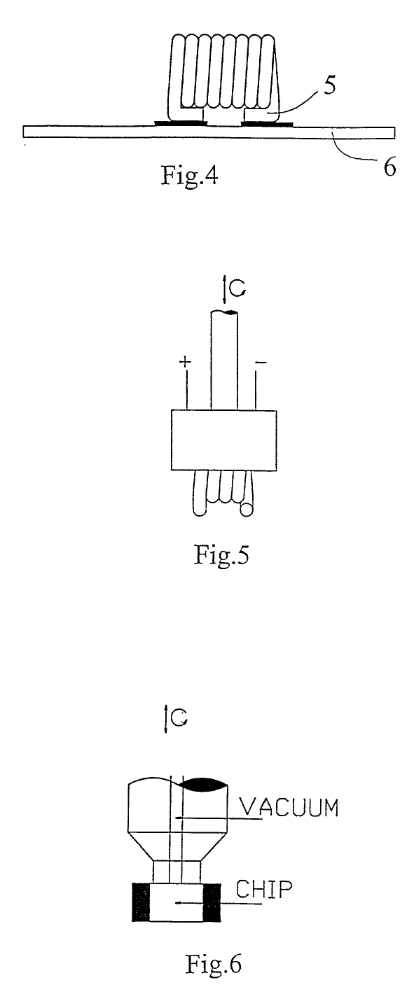

FIG. 4 shows the air coil in accordance with the invention mounted on a printed circuit board using SMD technology,

FIG. 5 shows an electromagnetic automatic mounting machine, and

FIG. 6 shows an automatic mounting machine using vacuum technology.

Conventional coils 1, as shown in FIG. 1, have the problem that after winding air gaps are formed between the turns 2. However, these air gaps affect the electromagnetic properties of the coil 1. Therefore, the turns 2 of the coil in accordance with the invention as shown in FIG. 2 consist of magnetic wire, as a result of which the turns 2 are held together without any further means. Thus, after winding the coil 1 retains its final shape and no air gaps as shown in FIG. 1 are formed. Moreover, an automatic mounting machine can distinguish between different coil types by means of a magnetic sensor on the basis of the magnetization which differs in magnitude and orientation depending on the length and size of the coil 1. In order to optimize the coil 1 for high frequency uses the magnetic wire is provided with a cladding 3 of gold, silver, copper or another well conducting material prior to winding. FIG. 3 shows the coil in accordance with the invention mounted on a printed circuit board 6. The coil leads are then passed through bores 4 in the printed circuit board and the coil is secured from the underside, for example by means of a soldering operation. Alternatively, the coil 1 shown in FIG. 4 is secured to the upper surface without the bores 4 by means of SMD technology. For this purpose, the coil has specially bent terminal lugs 5, which are mounted directly onto the printed circuit board 6.

During the mounting process shown in FIG. 5 the coils 1 are picked up by the automatic mounting machine with the aid of an electromagnet and are placed onto the printed circuit board 6, aligned and secured. Alternatively, as is shown in FIG. 6, the coils 1 can be picked up by the automatic mounting machine by means of a vacuum and can then be mounted.

1. An air coil (1) having a plurality of turns (2), characterized in that the turns (2) include a magnetic material.

2. An air coil (1) having a plurality of turns (2), characterized in that the turns (2) have an outer layer (3) for carrying an electric current and a magnetic material in their interior.

3. A coil (1) as claimed in claim 1, characterized in that the coil (1) is an air coil for high frequency uses and the turns (2) of the air coil are clad with a material having good high frequency properties, particularly copper, gold or silver.

4. A coil (1) as claimed in claim 1 or 2, characterized in that the shape and the orientation in which the coil (1) is to be mounted can be detected on the basis of the type and degree of magnetization of the coil (1).

5. A coil (1) as claimed in claim 1 or 2, characterized in that the coil (1) is adapted to be mounted on a printed circuit board (6) by means of an automatic mounting machine, which picks up the coil (1) and places it onto the printed circuit board (6) by an electromagnetic force or vacuum force.
